(19) United States
(12) Patent Application Publication
(10) Pub. No.: US 2026/0327067 A1
(43) Pub. Date: Oct. 22, 2026

(54) METHOD FOR MANUFACTURING A MICROELECTROMECHANICAL COMPONENT AND A MICROELECTROMECHANICAL COMPONENT

(71) Applicant: Robert Bosch GmbH, Stuttgart (DE)

(72) Inventors: Christian Foerster, Roseville, CA (US); Jochen Reinmuth, Reutlingen (DE); Michaela Anne Mitschke, Reutlingen (DE); Nils Felix Kuhlmann, Ehningen (DE)

(21) Appl. No.: 19/550,959

(22) Filed: Feb. 26, 2026

(30) Foreign Application Priority Data
Mar. 17, 2025 (DE) 10 2025 110 174.4

(51) Int. Cl. B81C 1/00; B81B 7/00

(52) U.S. Cl. CPC B81C 1/00285; B81B 7/0038; B81B 2201/0235; B81B 2201/0242; B81B 2207/012; B81B 2207/07; B81C 2203/0145

(57) ABSTRACT

A method of producing a microelectromechanical component. A carrier with a MEMS chip arranged on the carrier is provided. The MEMS chip has a frame structure arranged on the upper side of the carrier and a cap arranged on the frame structure. The carrier, the frame structure, and the cap enclose a cavern. A MEMS sensor is arranged in the cavern. An access channel that extends through the cap and opens into the cavern is created for introducing a medium and/or for setting a cavern pressure. The access channel is sealed with a laser, wherein a sealing nose that seals the access channel is formed on a side of the cap facing away from the carrier. The sealing nose is embedded in a protective material.

### FIELD

The present disclosure relates to a method for producing a microelectromechanical component, and to a microelectromechanical component.

### BACKGROUND INFORMATION

The use of a laser to seal a cavern of a microelectromechanical component (MEMS component) is described in the related art.

Sealing the cavern using a laser can also be referred to as laser resealing. A sealing nose or sealing tip is typically formed in the region of the seal. Since the MEMS component may be fragile in the region of the seal, it is conventional to provide a local recess in the region of an access channel to the cavern, in which the sealing nose is formed in such a way that it is completely arranged in the recess.

Typically, a MEMS chip is arranged on an application-specific integrated circuit (ASIC chip). However, when using an ASIC chip, which is significantly smaller compared to the MEMS chip, the ASIC chip must be arranged on the MEMS chip. This creates the risk of damaging the sealing region, which could impair the MEMS chip or cause it to fail.

For example, a crack may form in the sealing region. This can cause a leak in the seal, resulting in a change in cavern pressure and sensor failure. The cause of the crack could be, for example, a recess that is not deep enough. Furthermore, an uneven distribution of force due to an uneven adhesive bond between the ASIC chip and the MEMS chip can damage the seal region.

Furthermore, an air bubble is trapped in the region of the recess when the ASIC chip is arranged on the MEMS chip. Thermal expansion of the air bubble can cause mechanical stress on the ASIC chip. This can cause characteristic curve drifts, posing a risk of operation outside the specifications of the MEMS chip.

### SUMMARY

An object of the present disclosure is to specify an improved method for producing a MEMS component and to provide an improved MEMS component. This object may be achieved by a method for producing a MEMS component and by a MEMS component having certain features of the present disclosure. Advantageous developments are disclosed herein.

According to an example embodiment, a method for producing a microelectromechanical component comprises the following method steps. A carrier is provided with at least one microelectromechanical sensor chip arranged on the carrier. The carrier has a upper side and a lower side opposite the upper side. The microelectromechanical sensor chip has a frame structure arranged on the upper side of the carrier and a cap arranged on a side of the frame structure facing away from the carrier. The carrier, the frame structure, and the cap enclose a cavern. At least one microelectromechanical sensor structure is arranged in the cavern. An access channel that extends through the cap and opens into the cavern is created for introducing a medium and/or setting a cavern pressure. The access channel is sealed with a laser, wherein a sealing nose that seals the access channel is formed on the side of the cap facing away from the carrier. The sealing nose is embedded in a protective material.

The microelectromechanical component will also be referred to as the MEMS component in the following description. Likewise, the microelectromechanical sensor chip will be referred to as the MEMS chip in the following. Accordingly, the microelectromechanical sensor structure is also referred to as a MEMS sensor.

In one example embodiment, the microelectromechanical sensor Structure comprises at least one acceleration sensor and/or at least one rotation rate sensor. The MEMS chip therefore has at least one MEMS sensor that is arranged in the cavern.

During the method, an access channel to the cavern is first created. The access channel to the cavern can be created for example by etching. The access channel makes it possible to introduce a medium into the cavern and/or to set a cavern pressure. For example, the access channel can be created to introduce a gas into the cavern before the cavern is sealed. For example, an inert gas can be introduced into the cavern.

Additionally, for example a gas pressure can be set.

Alternatively, it is possible to introduce a liquid medium into the cavern via the access channel.

Alternatively or additionally, the access channel can be created, for example, to introduce an etching medium into the cavern. In this case, the etching medium can be introduced into the cavern for example to produce the microelectromechanical sensor structure, such as to expose moving elements of the MEMS sensor. Alternatively or additionally, the access channel can be created to introduce a coating material into the cavern. This may also be necessary, for example, during the production of the MEMS sensor.

Once the access channel has been created, a medium can thus be introduced into the cavern, such as a gas, a liquid medium, an etching medium, or a coating material. However, it is not absolutely necessary that a specific medium is actively introduced into the cavern. For example, it may be sufficient to create the access channel in order simply to set the cavern pressure without introducing a selected medium. In this case, after the access channel has been created, only the setting of the cavern pressure can take place, if this is necessary for the proper operation of the MEMS sensor.

In any case, in the method, the cavern is subsequently sealed.

This is done using a laser, i.e. using a laser reseal. During laser resealing, a material of the cap of the MEMS chip in the region of the access channel is melted using the laser. The cap may contain silicon, for example, but it may also contain a different material. When the cap material melts in the region of the access channel, a sealing nose forms, which is initially liquid and then solidifies as soon as the laser is no longer directed onto the region to be sealed. The sealing nose can also be referred to as a sealing tip.

The method is based on the idea of protecting the sealing nose and the sealing region. This is achieved by embedding the sealing nose in the protective material, i.e., the sealing nose is at least partially embedded in the protective material, namely a part of the sealing nose accessible on the cap. The sealing nose is protected by the protective material without necessarily having to create a recess in the cap, in which recess the sealing nose is formed. Creating a recess is an expensive and time-consuming process that can be advantageously omitted in the production of the MEMS component.

Furthermore, the protective material can be applied directly at wafer level after the access channel has been sealed. The sealing nose is therefore well protected not only in the final MEMS component but throughout the entire further processing.

Special pick-up tools that leave out the region of the sealing nose and access channel to protect this region are also not required during production.

For example, in one example embodiment the sealing nose is embedded in the protective material by the protective material being arranged as a protective layer on the side of the cap facing away from the carrier. This variant advantageously avoids creating a recess in the cap.

In another example embodiment, however, a recess can be created on the side of the cap facing away from the carrier in the region of the access channel, whereby the access channel opens into the recess. The sealing nose is arranged in the recess. The sealing nose can, for example, be arranged completely within the recess so that it does not protrude beyond the side of the cap facing away from the carrier. The sealing nose is embedded in the protective material by the protective material being arranged in the recess. Advantageously, this allows the MEMS component to have a small component height perpendicular to the upper side of the carrier.

In one example embodiment, the protective material is applied to the cap using an inkjet process. Both in the variant where the protective material is arranged as a protective layer on the side facing away from the carrier and in the variant where the protective material is arranged in the recess, the protective material can be applied to the cap using the inkjet process.

In one example embodiment, the protective material comprises one of the following materials: an organic material, a polymer, a photoresist. For example, the protective material can contain an imide, such as polyimide. Advantageously, imides are particularly temperature-stable and chemically resistant.

However, the protective material can also comprise a different material. The protective material generally preferably comprises a dielectric material. Depending on the choice of protective material, the protective material can be applied to the cap using the inkjet process or alternatively using another suitable method.

In one example embodiment, the protective material is planarized on a side facing away from the cap. Advantageously, this results in the protective material having a particularly even surface.

This allows for further construction of the MEMS component, as the surface of the MEMS chip is prepared for any type of stack Structure. Furthermore, planarizing the protective material allows for the production of a MEMS component with a smaller height. Planarization of the protective material can occur when the protective material is arranged as a protective layer on the cap. However, the planarization of the protective material can also occur if the protective material is arranged in the recess and protrudes from the recess.

In one example embodiment, an application-specific integrated circuit is arranged on the side of the cap facing away from the carrier. The application-specific integrated circuit is also referred to as an ASIC chip in the following. In a cross section parallel to the carrier, the ASIC chip preferably has a smaller footprint than the MEMS chip, although this is not mandatory.

Advantageously, the sealing nose formed in the cap is also protected in the configuration with the ASIC chip on the MEMS chip, since the sealing nose is embedded in the protective material on the side of the cap facing away from the carrier.

This means that the production of the MEMS component is not limited to the configuration with a MEMS chip on an ASIC chip.

However, an ASIC chip of which the cross section parallel to the carrier is smaller than a cross section of the MEMS chip parallel to the carrier requires that the ASIC chip be arranged on the MEMS chip. In this case, the sealing nose is nonetheless Still well protected, as it is embedded in the protective material. If the protective layer is planarized beforehand, a particularly good and mechanically sound connection between the MEMS chip and the ASIC chip can advantageously be achieved.

Another advantage of the method is that no cavity, such as an air bubble or a gas-filled cavity, is formed in the region of the sealing nose, since even in the variant of the method in which the recess is created in the cap and the ASIC chip is then arranged on the MEMS chip, the recess is filled with the protective material. Advantageously, the MEMS component is formed stably in the region of the seal or sealing nose, because it has no cavity.

If, on the other hand, the protective material is arranged as a protective layer on the cap, there is also the advantage that an even distribution of force between the MEMS chip and other chips arranged thereon is achieved.

In one example embodiment, the microelectromechanical sensor chip is arranged on a circuit board. The carrier is arranged with its lower side on another upper side of the circuit board. A first contact pad is arranged on the upper side of the carrier and outside the cavern. A second contact pad is arranged laterally next to the carrier on the circuit board. The application-specific integrated circuit has two additional contact pads on a side facing away from the cap. The first contact pad and the second contact pad are each electrically connected to another contact pad by a bonding wire. The protective material is arranged exclusively on the side of the cap facing away from the carrier.

The ASIC chip is designed to control and/or read the MEMS chip. The first contact pad, which is arranged on the upper side of the carrier, advantageously always remains free of the protective material during production and is therefore accessible for electrical contacting, since the protective material is arranged exclusively on the cap of the MEMS chip.

This means in particular that the protective material is not arranged on the upper side of the carrier, so that the first contact pad remains free of the protective material. In principle, the protective material in each of the described embodiments can be arranged exclusively on the side of the cap facing away from the carrier.

In one example embodiment, the microelectromechanical sensor chip and the application-specific integrated circuit are embedded in a molding material arranged on the further upper side of the circuit board. This advantageously protects both the MEMS chip and the ASIC chip.

According to an example embodiment, a microelectromechanical component comprises a microelectromechanical sensor chip with a carrier having a upper side and a lower side opposite the upper side, a frame structure arranged on the upper side and a cap arranged on a side of the frame structure facing away from the carrier. The carrier, the frame structure, and the cap enclose a cavern. At least one microelectromechanical sensor structure is arranged in the cavern. An access channel for introducing a medium and/or setting a cavern pressure extends through the cap and opens into the cavern. The access channel in the cap is sealed by a sealing nose formed on a side of the cap facing away from the carrier. The sealing nose is embedded in a protective material.

In one example embodiment, the protective material is arranged as a protective layer on the side of the cap facing away from the carrier, and the sealing nose is embedded in the protective layer.

In one example embodiment, a recess is formed on the side of the cap facing away from the carrier in the region of the access channel, whereby the access channel opens into the recess. The sealing nose is arranged in the recess. The protective material is arranged in the recess. The sealing nose is embedded in the protective material.

In one example embodiment, an application-specific integrated circuit is arranged on the side of the cap facing away from the carrier.

In one example embodiment, the microelectromechanical sensor chip is arranged on a circuit board. The carrier is arranged with its lower side on another upper side of the circuit board. According to an example embodiment, a first contact pad is arranged on the upper side of the carrier and outside the cavern. A second contact pad is arranged laterally next to the carrier on the upper side of the circuit board. The application-specific integrated circuit has two additional contact pads on a side facing away from the cap. The first contact pad and the second contact pad are each electrically connected to another contact pad by a bonding wire. The protective material is arranged exclusively on the side of the cap facing away from the carrier.

In one example embodiment, the microelectromechanical sensor chip and the application-specific integrated circuit are embedded in a molding material arranged on the further upper side of the circuit board.

The method for producing the MEMS component is explained in detail below in conjunction with the figures.

### BRIEF DESCRIPTION OF THE DRAWINGS

FIG. 1 shows a wafer composite with a plurality of MEMS chips in a lateral sectional view and access channels made in the MEMS chips.

FIG. 2 shows the wafer composite of FIG. 1 with sealed access channels in a lateral sectional view.

FIG. 3 shows the wafer composite of FIG. 2 with protective layers arranged on the MEMS chips in a lateral sectional view.

FIG. 4 shows the wafer composite of FIG. 3 with planarized protective layers in a lateral sectional view.

FIG. 5 shows another wafer composite with a plurality of MEMS chips in a lateral sectional view and recesses created in the region of sealed access channels of the MEMS chips.

FIG. 6 shows the wafer composite of FIG. 5 with a protective material arranged in the recesses.

FIG. 7 shows a MEMS component with an ASIC chip arranged on the MEMS chip.

### DETAILED DESCRIPTION OF EXAMPLE EMBODIMENTS

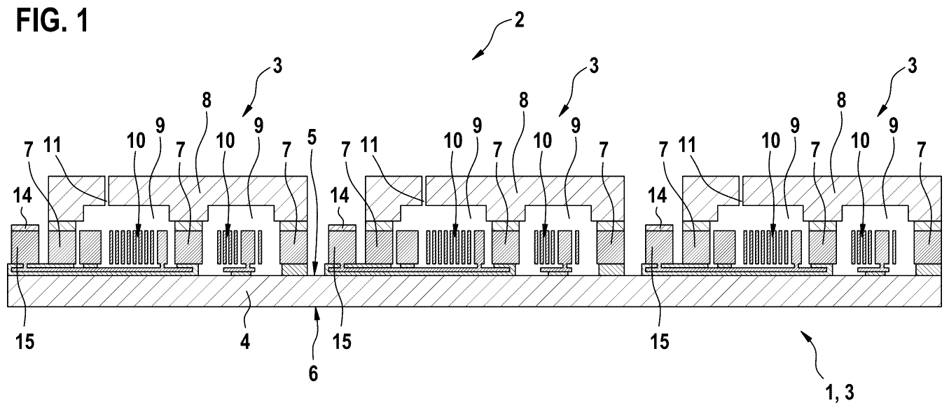

FIG. 1 to 4 schematically show method steps of a method for producing a plurality of MEMS components 1. As part of the method, first a wafer composite 2 with a plurality of MEMS chips 3 is provided, which is subsequently processed. FIG. 1 to 4 show the wafer composite 2 after each successive method step and each in a schematic cross-sectional view.

The wafer composite comprises one wafer 4. The wafer can, for example, contain silicon. The following description also applies accordingly to a method in which only one MEMS component 1 is produced. In this case, the wafer 4 can also be referred to as a substrate 4. In general, the method therefore provides a carrier 4 with at least one MEMS chip 3 arranged on the carrier 4. FIG. 1 shows by way of example that a total of three MEMS chips 3 are arranged on the carrier 4.

The carrier 4 has an upper side 5 and a lower side 6 opposite the upper side 5. The MEMS chips 3 each have a frame structure 7 arranged on the upper side 5 of the carrier 4 and a cap 8 arranged on a side of the frame structure 7 facing away from the carrier 4. The carrier structure 4, the frame structures 7 and the caps 8 each enclose a cavern 9. Like the carrier 4, the frame structures 7 and the caps 7 can also, for example, comprise silicon. The connection of the frame structures 7 to the carrier 4 and the connection of the caps 8 to the frame Structures 7 in order to enclose the caverns 9 can be carried out using bonding techniques, for example. Such connection techniques are conventional and are not explained in more detail below. However, the connection regions between the aforementioned elements are indicated in FIG. 1.

In the cross-sectional view of FIG. 1, the frame structures 7 have, by way of example, support structures arranged in the middle of the caverns, which extend between the upper side 5 of the carrier 4 and the caps 8. FIG. 1 should not be understood as meaning that the carrier structures divide the caverns 9 into separate chambers. Rather, the MEMS chips 3 each have a contiguous cavern 9.

At least one microelectromechanical sensor structure 10 is arranged in each of the caverns 9. As an example, FIG. 1 shows that two MEMS sensors 10 are arranged in each of the caverns 9 of the MEMS chips 3. In the exemplary embodiment, a first MEMS sensor 10 is formed as an acceleration sensor. A second MEMS sensor 10 is formed as a rotation rate sensor. The MEMS sensors 10 have structures anchored to the carrier 4 and movable structures. The MEMS sensors 10 are not described in detail as such, since such sensors with fixed and moving elements for measuring accelerations and/or rotation rates are generally conventional.

Typically, it is necessary to introduce a medium into the caverns 9, such as an inert gas, to protect the MEMS sensors 10. Furthermore, it may be necessary to set a sensor-specific cavern pressure to ensure proper or optimal operation of the MEMS sensors 10. In addition to gaseous media, liquid media can also be introduced into the caverns 9. For example, it may be necessary to introduce an etching agent into the caverns 9, for instance to expose moving elements of the MEMS sensors 10.

Furthermore, it is possible that coating materials are also introduced into the caverns 10, for example as part of a layer Structure of the MEMS sensors 10.

For this purpose, an access channel 11 to the caverns 9 is created in each case in the method. The access channels 11 are here created in the caps 8. The access channels 11 extend, for example, along a direction perpendicular to the upper side 5 of the carrier 4 through the caps 8 and each open into the caverns 9. The creation of the access channels 11 can take place, for example, by etching. However, the access channels 11 can also be created in the caps 8, for example using photolithography or using a laser.

After creation, the introduction of a medium and/or the setting of a cavern pressure in the caverns 9 can take place. The caverns must then be sealed, for example to prevent a medium introduced into the caverns 9 from escaping from the caverns 9 and/or to maintain a cavern pressure set in the caverns 9.

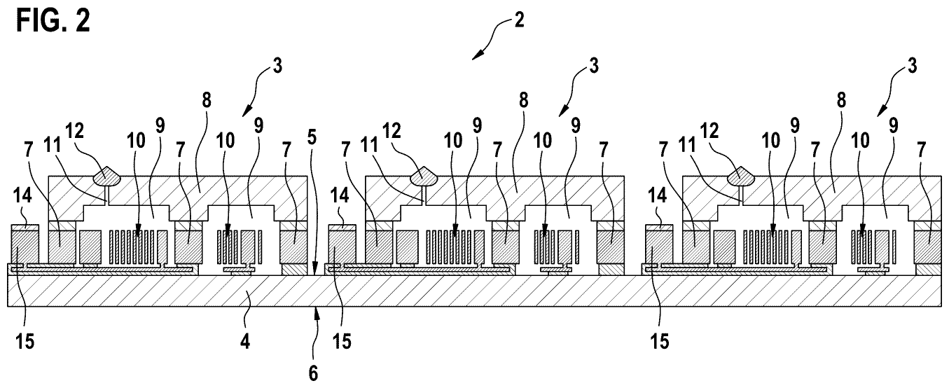

FIG. 2 schematically shows a state subsequent in time to FIG. 1 during the production of the MEMS components 1. Reference signs are retained for similar and identical elements.

The access channels 11 were sealed with a laser. In this process, sealing noses 12 were formed in the caps 9, which seal the access channels 11. The sealing noses 12 were each formed on the sides of the caps 8 facing away from the carrier 4. The sealing noses 12 are formed by a laser being directed onto the access channels 11, the energy of which is sufficient to melt a material of the caps 8 in the region of the access channels 11. Sealing the access channels 11 with the laser can also be referred to as laser resealing. This can at least partially involve an ablation process. After the material melted in the region of the access channels 11 hardens, the sealing noses 12 remain, which seal the access channels 11. The sealing noses 12 can also be referred to as sealing tips 12.

In the region of the sealed access channels 11 or in the region of the sealing noses 12, the MEMS chips 3 may be fragile. A sealing nose 12 projecting past the cap 8 in a vertical direction with respect to the upper side 5 of the carrier 4 can also break off, thereby ventilating the cavern 9.

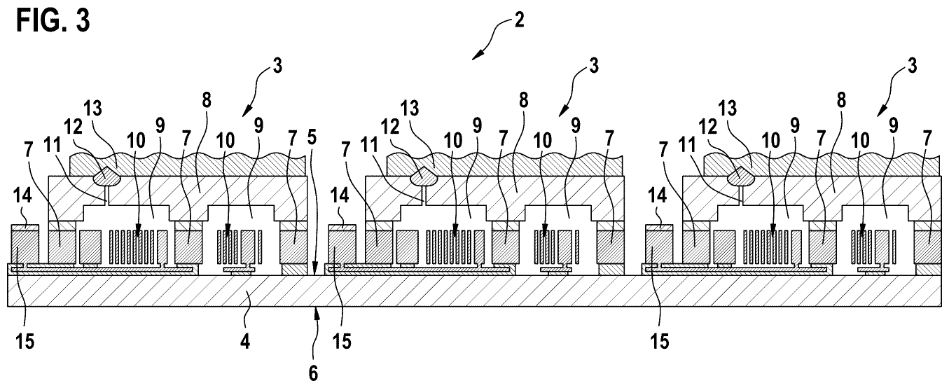

To solve this problem, it is proposed to embed the sealing noses 12 in a protective material 13. FIG. 3 schematically shows a state subsequent in time to FIG. 2 during the production of the MEMS components 1. Reference signs are retained for similar and identical elements.

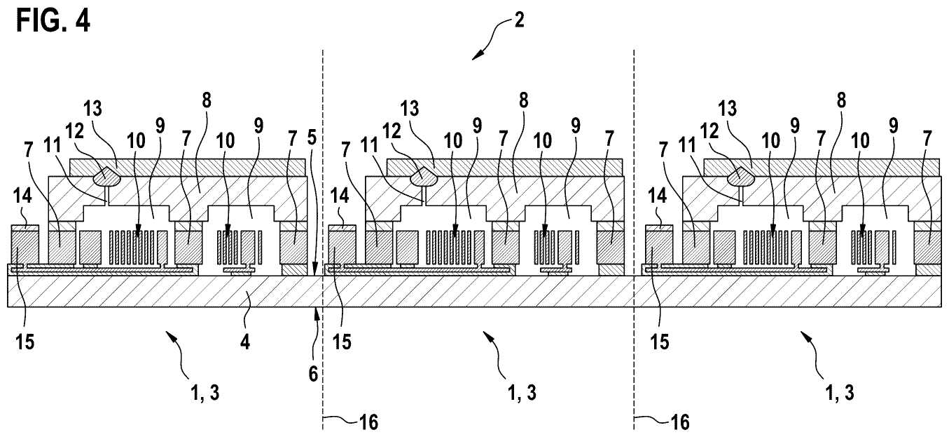

In the variant shown in FIG. 4, the sealing noses 12 are embedded in the protective material 13 by the protective material 14 being arranged as a protective layer on the sides of the caps 8 of the MEMS chips 3 facing away from the carrier 4. As a result, a portion of the sealing noses 12 projecting past the caps 8 is covered by or embedded in the protective material 13.

The protective material 13 can for example comprise an organic material, a polymer such as polyimide, or a photoresist.

However, the protective material 13 can also comprise a different material, in particular a dielectric material. The protective material 13 can for example be arranged on the caps 8 using an inkjet process. The inkjet process offers the particular advantage that the protective material 13 can be specifically arranged exclusively on the caps 8, in particular in the region of the sealing noses 12, in order to embed them.

This leaves regions between the MEMS chips 3 free of the protective material 13.

In the exemplary embodiment, first contact pads 14 are arranged on the upper side 5 of the carrier 4 and outside the cavern 9 for the electrical contacting of the MEMS chips 3. For example, the first contact pads 14 are each arranged on a projection 15 or pedestal arranged on the upper surface 5 of the carrier 4, namely on a side of the projections 15 facing away from the upper surface 5. However, the projections 15 may also be omitted. In this case, for example, the first contact pads 14 are arranged on the upper side 5 of the carrier 4. As an example, a first contact pad 14 is provided for each MEMS chip 3.

By the protective material 13 being arranged exclusively on the caps 8 of the MEMS chips 3, the regions between the MEMS chips 3, within which the first contact pads 14 are arranged, remain free of the protective material 13. As a result, the first contact pads 14 are immediately accessible for the electrical contacting. Otherwise, the protective material 13 would have to be opened in the region of the first contact pads 14.

The protective layers arranged on the caps 8 can have a certain roughness and/or waviness as shown in FIG. 3. FIG. 4 schematically shows a state subsequent in time to FIG. 3 during the production of the MEMS components 1. Reference signs are retained for similar and identical elements.

The protective material 13 has been planarized. More precisely, the protective material 13 was planarized on the sides facing away from the caps 8. This can be carried out for example by chemical mechanical polishing (CMP). The method step of planarizing the protective material 13 can also be omitted.

However, the planarization of the protective material 13 has the advantage that, on the one hand, the component height is reduced and, on the other hand, further process steps in the production of the MEMS components 1 are made possible which relate to the further layer-like structure. For example, an ASIC chip can be arranged on the protective material and better connected to MEMS chips 3 if a surface of the protective material 13 is planarized. The carrier 4 can be divided in regions between the microelectromechanical sensor chips 3 to obtain individual MEMS chips 3. In FIG. 4, singulation planes 16 running between the MEMS chips 3 and transversely to the carrier 4 are indicated, along which the carrier 4 is divided. Furthermore, the singulation planes 16 do not run in the regions of the first contact pads 14, but rather between the first contact pads 14 and the MEMS chips 3. The singulated MEMS chips 3 can be referred to as completed MEMS components 1.

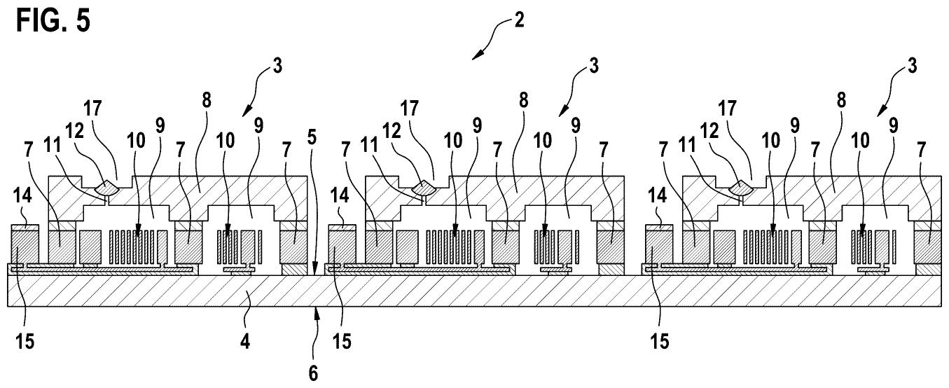

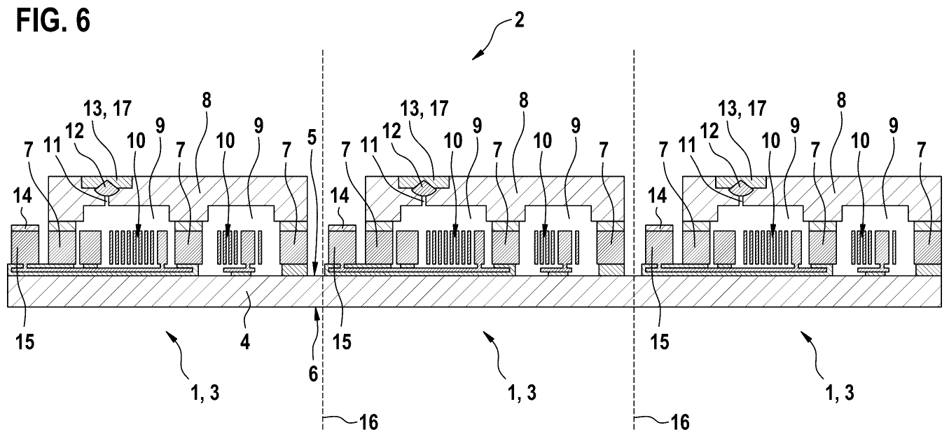

FIGS. 5 and 6 show an alternative method to the method of FIG. 1 to 4. In the following description, substantially the differences from the method of FIG. 1 to 4 will be explained.

FIG. 5 schematically shows a state subsequent in time to FIG. 1 during the production of the MEMS components 1. Reference signs are retained for similar and identical elements.

As in the method of FIG. 1 to 4, access channels 11 were created in the caps 8, each opening into the caverns 9. Before the caverns 9 were sealed, recesses 17 were formed around the region of the access channels 11. The access channels 11 open into the recesses 17. In other words, the access channels 11 connect the caverns 9 with the recesses 17.

Since the access channels 11 open into the recesses 17, the sealing noses 12 are arranged in the recesses 17. Preferably, the sealing noses 12 are arranged completely in the recesses 17 and do not protrude past the caps 8.

FIG. 6 schematically shows a state subsequent in time to FIG. 5 during the production of the MEMS components 1. Reference signs are retained for similar and identical elements.

The protective material 13 has been arranged in the recesses 17. As a result, the sealing noses 12 are embedded in the protective material 12. For example, the protective material 13 is flush with the caps 8. However, the protective material 13 can also protrude from the recesses 17 past the caps 8. In this case, the protective material 13 can be planarized so that it is flush with the caps 8, which is not absolutely necessary but can simplify the further construction.

In this variant as well, the protective material 13 is arranged exclusively on the caps 8 of the MEMS chips 3, so that the first contact pads 14 remain free of the protective material 13. In contrast to the variant shown in FIG. 1 to 4, the protective material 13 is deposited locally on the caps 8, namely in the recesses 17. In addition, however, a protective layer 13 according to FIG. 3 or FIG. 4 can also be arranged on the caps 8 if necessary. This comes into consideration, for example, if the sealing noses 12 protrude from the recesses 17 past the caps 8 because no sufficiently deep recesses 17 can be formed.

The method for producing the MEMS components 1 also has the advantage that the arrangement of the protective material 13 or the embedding of the sealing noses 12 in the protective material 13 can already be carried out at the wafer level, i.e. before singulation of the MEMS chips 3, which saves effort and costs.

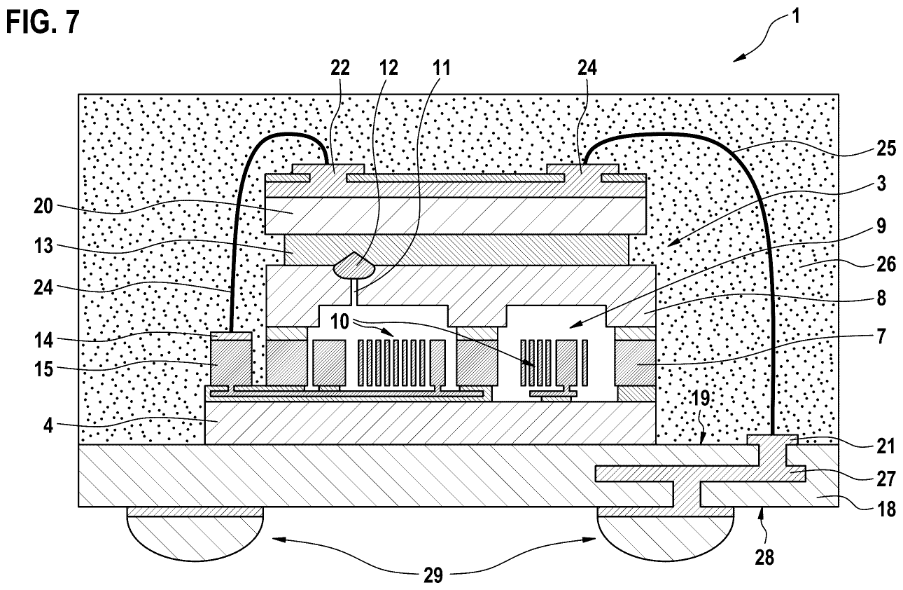

FIG. 7 shows a schematic example of a state subsequent in time to FIG. 4 during the production of the MEMS components 1, wherein only one singulated MEMS component 1 is shown. By way of example only, the access channel 11 was sealed without creating a recess 17 as shown in FIGS. 4 and 5. However, the following description also applies accordingly to MEMS components 1 produced according to FIGS. 4 and 5. The method steps illustrated in FIG. 7 can therefore be carried out according to the method steps shown in FIG. 5. However, the method steps shown in FIG. 7 are only optional, and can also be omitted. Reference signs are retained for similar and identical elements.

After the sealing nose 12 was embedded in the protective material, the MEMS chip 3 was arranged on a printed circuit board 18 (PCB). The carrier 4 of the MEMS chip 3 was arranged with its lower side 6 on another upper side 19 of the circuit board 18. However, the MEMS chip 3 can also be arranged on a different substrate, such as a ceramic substrate.

In addition, an ASIC chip 20 was arranged on the side of the cap 8 facing away from the carrier. In the exemplary embodiment, the ASIC chip 20 was arranged on a surface of the protective material 13 that faces away from the cap 8 of the MEMS chip 3.

The ASIC chip 20 is designed to control and/or read the MEMS chip 3.

For the electrical contacting of the ASIC chip 20, a second contact pad 21 is arranged on the further upper surface 19 of the circuit board 18. The second contact pad 21 is arranged laterally next to the MEMS chip 3 on the circuit board 18, i.e. laterally next to the carrier 4. Moreover, the ASIC chip 20 has two additional contact pads 22, 23. The other contact pads 22, 23 are arranged on a side of the ASIC chip 20 facing away from the MEMS chip 3.

A first additional contact pad 22 of the ASIC chip 20 is connected to the first contact pad 14 by a first bonding wire 24. A second additional contact pad 23 is connected to the second contact pad 21 by a second bonding wire 25. To protect the entire structure of the MEMS component 1, the MEMS chip 3 and the ASIC chip 20 were embedded in a molding material 26 arranged on the further upper side surface 19 of the circuit board 18. The molding material 26 can for example comprise a silicone.

The MEMS component 1 is surface-mountable and can therefore also be referred to as an SMD component (surface-mounted device, abbreviated to SMD). For surface mounting, the circuit board 18 has electrical feedthroughs 27 which extend from the further upper side 19 of the circuit board 18 to a further lower side 28 of the circuit board 18 which is opposite the further upper side 19, and which are connected to electrical terminals 29 on the further lower side 28.

The present disclosure can be used in connection with smartphones and tablets, for example, for the following applications: screen orientation; motion detection; device orientation; activity, gesture and context recognition; image stabilization; indoor SLAM (simultaneous localization and mapping); impact and free-fall detection; motion control.

In the context of wearable devices, augmented reality and virtual reality, the present disclosure can be used for the following applications: step counting; activity, gesture and context recognition; calorie counting; in-ear detection; sleep monitoring; elderly care; indoor navigation; position tracking; low-energy sensing, real-time motion detection, head movement tracking. In connection with drones, the present disclosure can be used for the following applications: orientation; altitude stabilization; flight control; motion tracking, motion control, balance; activity and gesture recognition.

In connection with robots, the present disclosure can be used for the following applications: navigation; boundary detection; dynamic path planning; indoor SLAM; air quality monitoring; blockage detection.

In the context of smart home technology, the present disclosure can be used for the following applications: burglary control; air quality monitoring; mold detection; air conditioning; floor level detection; indoor navigation.

The present disclosure can also be used in an industrial context for the following applications: water level detection;

navigation and control; motion and position tracking; energy management; predictive maintenance and control; motion and position tracking; energy management.

1-10. (canceled)

11. A method for producing a microelectromechanical component, comprising the following steps:
providing a carrier with at least one microelectromechanical sensor chip arranged on the carrier, wherein the carrier has an upper side and a lower side opposite the upper side, wherein the microelectromechanical sensor chip has a frame structure arranged on the upper side of the carrier, and a cap arranged on a side of the frame structure facing away from the carrier, wherein the carrier, the frame structure and the cap enclose a cavern, wherein at least one microelectromechanical sensor structure is arranged in the cavern;
creating an access channel that extends through the cap and opens into the cavern for introducing a medium and/or for setting a cavern pressure;
sealing the access channel with a laser, wherein a sealing nose that seals the access channel is formed on a side of the cap facing away from the carrier; and
embedding the sealing nose in a protective material.

12. The method according to claim 11, wherein the sealing nose is embedded in the protective material by the protective material being arranged as a protective layer on the side of the cap facing away from the carrier.

13. The method according to claim 11, wherein:
a recess is formed on the side of the cap facing away from the carrier in a region of the access channel, whereby the access channel opens into the recess, the sealing nose is arranged in the recess, and the sealing nose is embedded in the protective material by the protective material being arranged in the recess.

14. The method according to claim 11, wherein the protective material is planarized on a side facing away from the cap.

15. The method according to claim 11, wherein the protective material is arranged on the cap using an inkjet process.

16. The method according to claim 11, wherein an application-specific integrated circuit is arranged on the side of the cap facing away from the carrier.

17. The method according to claim 16, wherein:
the microelectromechanical sensor chip is arranged on a circuit board, the carrier is arranged with the lower side of the carrier on an upper side of the circuit board,
a first contact pad is arranged on the upper side of the carrier and outside the cavern,
a second contact pad is arranged laterally next to the carrier on the circuit board, the application-specific integrated circuit has two further contact pads on a side of the application-specific integrated circuit facing away from the cap,
the first contact pad and the second contact pad are each electrically connected to another contact pad by a bonding wire, and
the protective material is arranged exclusively on the side of the cap facing away from the carrier.

18. The method according to claim 17, wherein the at least one microelectromechanical sensor chip and the application-specific integrated circuit are embedded in a molding material arranged on the upper side of the circuit board.

19. A microelectromechanical component, comprising:
a microelectromechanical sensor chip with a carrier having an upper side and a lower side opposite the upper side, a frame structure arranged on the upper side of the carrier, and a cap arranged on a side of the frame structure facing away from the carrier,
wherein the carrier, the frame structure, and the cap enclose a cavern,
wherein at least one microelectromechanical sensor structure is arranged in the cavern,
wherein an access channel for introducing a medium and/or for setting a cavern pressure extends through the cap and opens into the cavern,
wherein the access channel in the cap is sealed by a sealing nose formed on a side of the cap facing away from the carrier, and
wherein the sealing nose is embedded in a protective material.

20. The microelectromechanical component according to claim 19, wherein the protective material includes one of the following materials: an organic material, a polymer, a photoresist.
